(19) United States
(12) Patent Application Publication
(10) Pub. No.: US 2012/0008258 A1
(43) Pub. Date: Jan. 12, 2012

(54) CLAMSHELL ELECTRONIC DEVICE

(75) Inventor: Hsiao-Jung Hsu, Taipei (TW)

(73) Assignee: GETAC TECHNOLOGY CORPORATION, HSINCHU (TW)

(21) Appl. No.: 12/833,877

(22) Filed: Jul. 9, 2010

(51) Int. Cl. H05K 7/00

(52) U.S. Cl. 361/679.01

(57) ABSTRACT

A clamshell electronic device includes a first body and a second body pivoted to each other and capable of rotating relative to each other. The first body has more than one signal connection port, and the second body has at least one side wall. When the second body is rotated and closed on the first body, the side wall of the second body shields the signal connection port of the first body.

### BACKGROUND OF THE INVENTION

1. Field of the Invention

The present invention relates to a structural design of an electronic device, and more particularly to a clamshell electronic device.

2. Related Art

With the rapid development of technology, the electronic industry has been developed at a tremendous pace. In modern times, electronic devices are commonly used. In order to prevent the electronic devices from being easily damaged, and in consideration of such factors as the requirements of light and thin design, the electronic devices may be designed as clamshell structures.

A conventional clamshell electronic device includes two bodies pivoted to each other. When the two bodies come close to each other, elements on the bodies can be protected, and when the two bodies are correspondingly opened, a user is allowed to use the device. In most cases, when a commercially available clamshell electronic device, such as a notebook computer, a clamshell personal digital assistant (PDA) or a clamshell cell phone, is used, some external computer peripheral devices are connected thereto. Therefore, at least one signal connection port, such as a universal serial bus (USB) connection port, an audio input/output connection port or a mouse or keyboard connection port, needs to be arranged on a side edge of the clamshell electronic device.

For example, notebook computers may not only be designed as common household or commercial notebook computers, but may further be designed as industrial or military notebook computers. The industrial or military notebook computers usually need to be used in environmental extremes. However, the signal connection ports of the notebook computer are exposed to the outside, and if the signal connection ports are contaminated with moisture or dust due to carelessness, a short circuit is easily caused, and even the entire electronic device fails. Therefore, a protecting mechanism for the signal connection port of the notebook computer is quite important.

For some currently commercially available protecting mechanisms for the signal connection port of the notebook computer, a cover is additionally provided to completely cover the signal connection port, or the signal connection port is designed as a lift-type structure. The lift-type structure refers to that when not being used, the signal connection port is maintained in a case of the notebook computer, and when being used, the signal connection port is lifted to the outside of the case.

However, since the above protecting mechanism designs for the signal connection port require providing a plurality of additional elements or changing the original layout design in the notebook computer, the integrity in appearance of the notebook computer is marred, and the integral structural design is excessively complex, thereby resulting in a significant increase in the manufacturing cost, and also resulting in increased operational complexity for users, such that the user cannot instinctively insert an electrical plug of the computer peripheral device into the signal connection port quickly and easily.

### SUMMARY OF THE INVENTION

In view of the above problems, the present invention is a clamshell electronic device, which can solve the problems that a conventional notebook computer has no protecting mechanism for exposed signal connection ports thereof, and the design of the protecting mechanism for the signal connection port is excessively complex, such that the manufacturing cost is increased, and it is not convenient for users to operate.

The present invention provides a clamshell electronic device, which comprises a first body and a second body. The first body has at least one signal connection port on a side edge thereof. The second body is rotatably pivoted to the first body, such that the second body has a closed position close to the first body and an opened position forming an angle with the first body. The second body has at least one side wall extending corresponding to the side edge of the first body. When the second body is located at the closed position, the side wall of the second body shields the signal connection port of the first body.

The clamshell electronic device of the present invention further comprises a moving member and a restoring component. One end of the restoring component is connected to the moving member, and the other end is connected to the second body. The moving member moves between a received position and a use position through the restoring component. When the second body is located at the closed position, the moving member is moved to the received position, and when the second body is located at the opened position, the moving member is moved to the use position.

The clamshell electronic device of the present invention has the following advantages. When the second body is located at the closed position, the side wall of the second body completely covers the exposed signal connection port of the first body, thereby protecting the signal connection port from being damaged due to external impacts or contamination with dust or moisture. When the second body is located at the opened position, the signal connection port is not shielded by the side wall and thus can be directly used, such that the user can conveniently and instinctively perform an electrical connection operation.

Further, since such a design does not mar the integrity in appearance of the clamshell electronic device, a simple integral design can be maintained for the appearance of the clamshell electronic device, such that both front and back sides of the clamshell electronic device can be used as the appearance side, thereby providing a desirable and pleasant appearance.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a clamshell electronic device at an opened position according to a first embodiment of the present invention;

FIG. 2 is a schematic view of the clamshell electronic device at a closed position according to the first embodiment of the present invention;

FIG. 3 is a schematic partial exploded view of the clamshell electronic device according to the first embodiment of the present invention;

FIG. 4A is a cross-sectional side view of the clamshell electronic device at the closed position according to the first embodiment of the present invention;

FIG. 4B is a cross-sectional side view of the clamshell electronic device at the opened position according to the first embodiment of the present invention;

FIG. 5 is a schematic partial exploded view of a clamshell electronic device according to a second embodiment of the present invention;

FIG. 6A is a cross-sectional side view of the clamshell electronic device at a closed position according to the second embodiment of the present invention;

FIG. 6B is a cross-sectional side view of the clamshell electronic device at an opened position according to the second embodiment of the present invention; and

FIG. 7 is a cross-sectional side view of a clamshell electronic device according to a third embodiment of the present invention.

### DETAILED DESCRIPTION OF THE INVENTION

A clamshell electronic device of the present invention comprises, but is not limited to, a notebook computer, a PDA, a cell phone, and other clamshell electronic devices. In the detailed description of the present invention below, the notebook computer is used as the most preferred embodiment of the present invention. However, the accompanying drawings are provided for reference and description only, but not intended to limit the present invention.

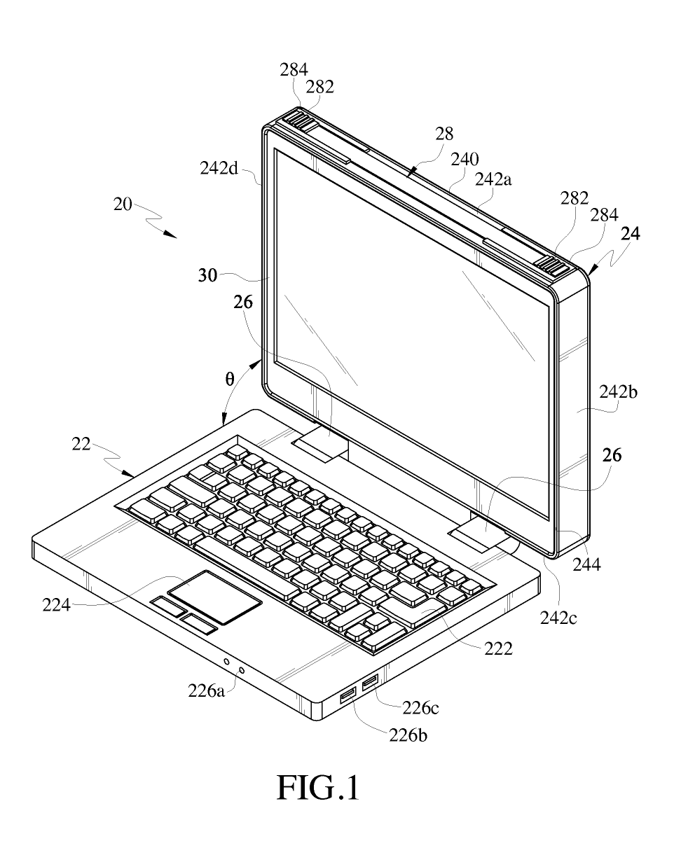

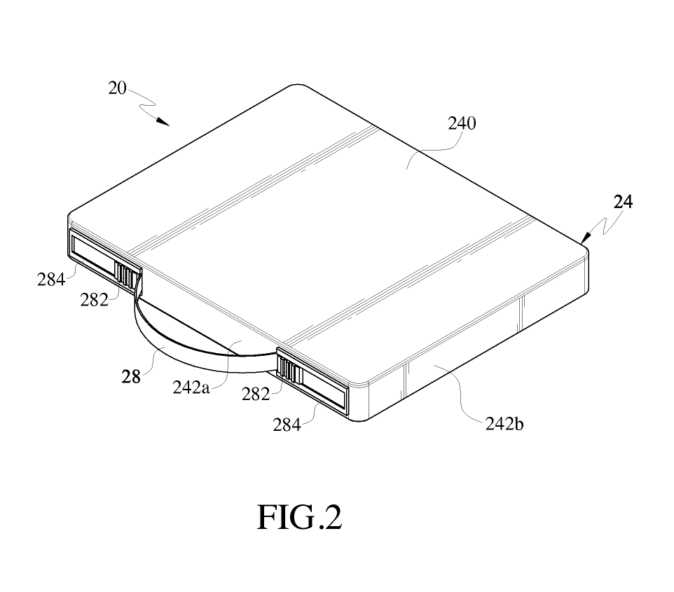

FIGS. 1 and 2 are schematic views of a first embodiment of the present invention. A clamshell electronic device 20 according to the first embodiment comprises a first body 22, a second body 24, and a pivoting component 26. In this embodiment, the first body 22 is a main body of the notebook computer, the first body 22 has a circuit layout (not shown) disposed therein for successfully executing preset functions of the clamshell electronic device 20, a keyboard 222 disposed on an upper surface of the first body 22, a cursor shift touch module 224 disposed adjacent to the keyboard 222, and a plurality of signal connection ports 226a, 226b, and 226c disposed on a side edge of the first body 22. The number and positions of the signal connection ports of the present invention may be adjusted according to practical application requirements, and are not limited to this embodiment.

The second body 24 is rotatably pivoted to the first body 22 through the pivoting component 26, such that the second body 24 has an opened position (as shown in FIG. 1) forming an angle θ with the first body 22, and a closed position (as shown in FIG. 2) close to the first body 22.

When the second body 24 is rotated through the pivoting component 26 and forms an angle θ with the first body 22, such that the keyboard 222 and the cursor shift touch module 224 located on the upper surface of the first body 22 are exposed and thus can be operated by a user, the position at which the second body 24 is located is called the opened position (as shown in FIG. 1). When the second body 24 is rotated through the pivoting component 26 and comes close to the first body 22, such that the keyboard 222 and the cursor shift touch module 224 located on the upper surface of the first body 22 are covered by the second body 24, the position at which the second body 24 is located is called the closed position (as shown in FIG. 2).

The second body 24 has a body portion 240 and four side walls 242a, 242b, 242c, and 242d extending corresponding to the side edge of the first body 22, and side edges of the four side walls 242a, 242b, 242c, and 242d are connected in sequence to form a rectangular structure. The body portion 240 has electronic components and circuits (not shown) therein. The side walls 242a, 242b, 242c, and 242d are made of a firm waterproof material, and extend from an outer frame of the body portion 240.

A handle 28 is disposed on the side wall 242a. A sliding block 282 is respectively disposed on two opposite ends of the handle 28, sliding chutes 284 corresponding to the sliding blocks 282 are disposed on the side wall 242a, and the sliding blocks 282 are slideably combined with the sliding chutes 284. Therefore, the handle 28 can be received close to the side wall 242a. The handle 28 can also be pulled outwards to form an arc shape for the user to grasp, such that the user can directly carry the clamshell electronic device 20 without additionally purchasing a hand bag. Further, since the clamshell electronic device 20 has an integral appearance, the clamshell electronic device 20 may be directly used as a hand bag.

When the second body 24 is located at the closed position, the side wall 242a shields the signal connection port 226a, and the side wall 242b shields the other signal connection ports 226b and 226c. In this manner, all the signal connection ports 226a, 226b, and 226c are shielded by the side walls 242a, 242b, 242c, and 242d, thereby achieving a good protecting effect.

Although in this embodiment, the second body 22 has four side walls 242a, 242b, 242c, and 242d, the present invention is not limited thereto. The number of the side walls is determined according to the positions of the signal connection ports and the integral structural design. In other embodiments of the present invention, the second body 22 only has the side walls 242a and 242b extending corresponding to the two side edges having the signal connection ports 226a, 226b, and 226c.

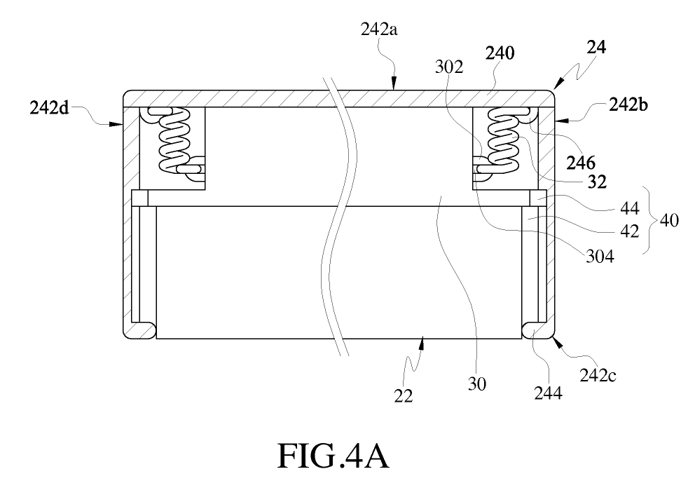

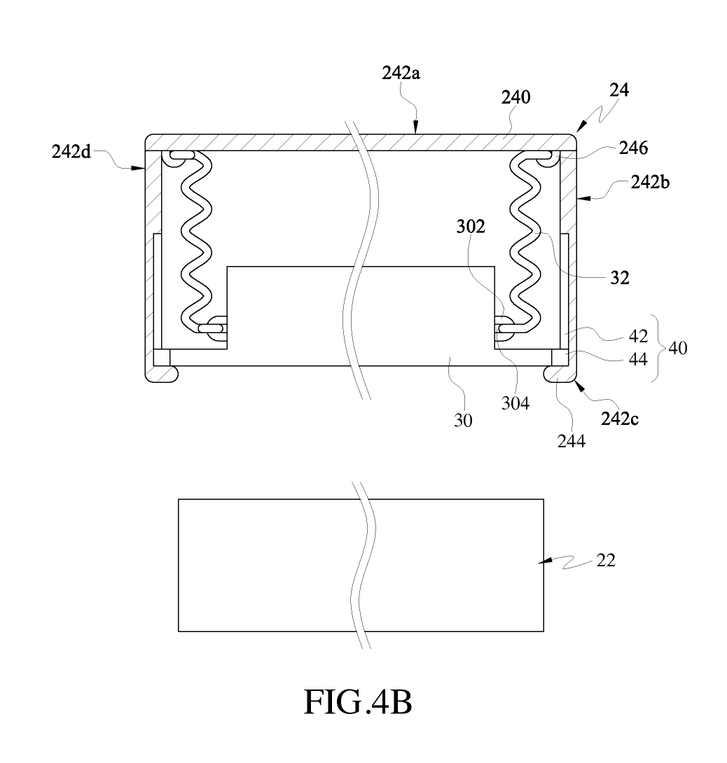

In this embodiment, a size of the body portion 240 of the second body 24 is slightly larger than a size of the first body 22, and the side walls 242a, 242b, 242c, and 242d extend from outer edges of one side of the body portion 240 facing the first body 22 when the second body 24 is located at the closed position (referring to FIGS. 4A and 4B). In other embodiments of the present invention, the side walls 242a, 242b, 242c, and 242d are bent and extend from side edges of the body portion 240, such that no matter whether the size of the body portion 240 is smaller than or equal to the size of the first body 22, the side walls 242a, 242b, 242c, and 242d are sufficient to correspondingly shield the signal connection ports 226a, 226b, and 226c.

In this embodiment, the pivoting component 26 is a link arm, and two ends of the link arm are respectively rotatably pivoted to the first body 22 and the second body 24. Compared with single-bearing pivoting, dual-bearing pivoting allows a more flexible rotation between the first body 22 and the second body 24, and further prevents the side walls 242a, 242b, 242c, and 242d from obstructing the movement of the second body 24 from the opened position to the closed position.

In order to further prevent moisture or dust from entering gaps between the side walls 242a, 242b, 242c, and 242d and the first body 22, a waterproof pad 244 is further disposed on outer edges of the side walls 242a, 242b, 242c, and 242d. When the second body 24 is located at the closed position, the waterproof pad 244 is in close contact with the side edge of the first body 22, such that the waterproof pad 244 blocks the gaps between the side walls 242a, 242b, 242c, and 242d of the second body 24 and the first body 22 (referring to FIG. 4A).

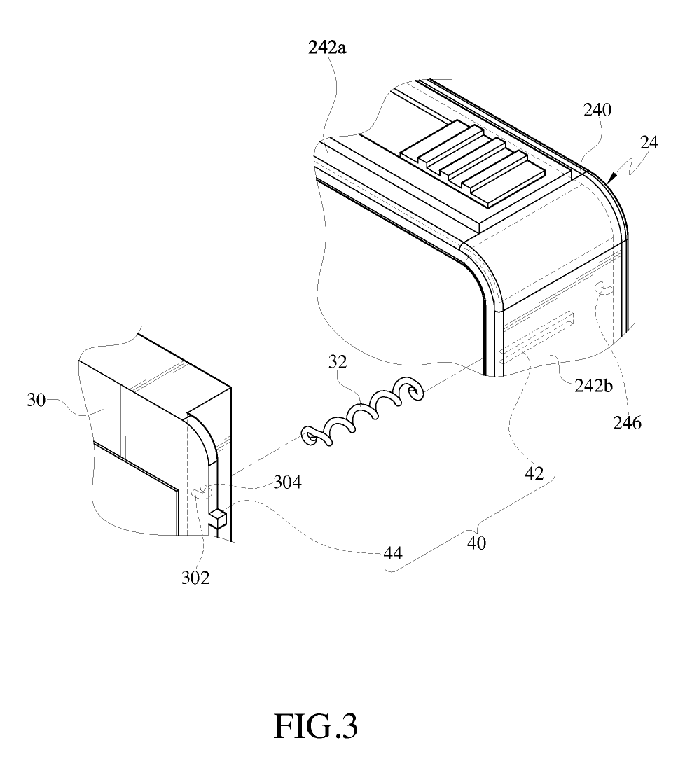

Referring to FIGS. 3, 4A, and 4B, the second body 24 has a moving member 30 and four restoring components 32 arranged therein. In this embodiment, the moving member 30 is a display screen, but according to other embodiments of the present invention, the moving member 30 is, for example, a keyboard or a touch pad, and is not limited to this embodiment. Side edges of the moving member 30 have a plurality of combining members 302, and each combining member 302 has a combining hole 304.

In this embodiment, each restoring component 32 is a compression spring. One end of the restoring component 32 is connected to the combing hole 304 of the moving member 30, and the other end is connected to one of a plurality of fixing holes 246 on the body portion 240 of the second body 24. When the second body 24 is located at the closed position, the moving member 30 is pushed by the first body 22, such that the moving member 30 moves to a received position close to the body portion 240, and the restoring components 32 are compressed (as shown in FIG. 4A). When the second body 24 is located at the opened position, the moving member 30 is pushed by elastic restoring forces of the restoring components 32 to move away from the body portion 240, such that the moving member 30 moves to a use position adjacent to the outer edges of the side walls 242a, 242b, 242c, and 242d (as shown in FIG. 4B). In this manner, when the second body 24 is located at the opened position, the periphery of the moving member 30 is not stopped by the side walls 242a, 242b, 242c, and 242d, so that the use of the clamshell electronic device 20 by the user is not affected.

In order to facilitate the movement of the moving member 30 between the use position and the received position, a guiding component 40 is further disposed between the moving member 30 and the second body 24. In this embodiment, the guiding component 40 comprises a plurality of sliding rails 42 and a plurality of sliding members 44. The sliding rails 42 are disposed on one side of the side walls 242a, 242b, 242c, and 242d adjacent to the moving member 30, the sliding members 44 are disposed on the side edges of the moving member 30 corresponding to the sliding rails 42, and the sliding members 44 are slideably disposed on the sliding rails 42.

The moving member 30 moves between the use position and the received position along the sliding rails 42, such that the moving member 30 will not be misaligned, offset, or otherwise improperly positioned. Definitely, besides disposing the sliding members 44 and the sliding rails 42 to guide the moving member 30, in other embodiments of the present invention, a plurality of sliding rails is also disposed on the side edges of the moving member 30, and a plurality of sliding chutes corresponding to the sliding rails is disposed on the side of the side walls 242a, 242b, 242c, and 242d adjacent to the moving member 30. Further, the sliding rails are slideably disposed in the sliding chutes.

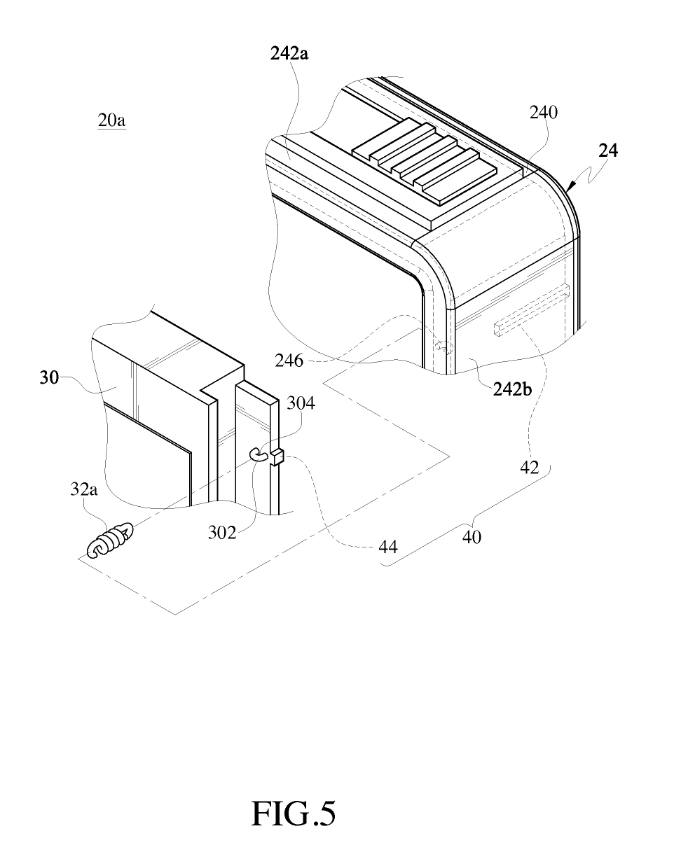

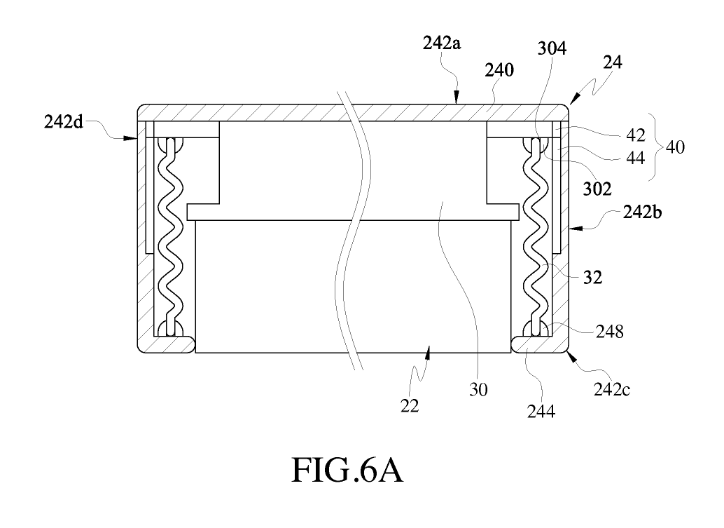

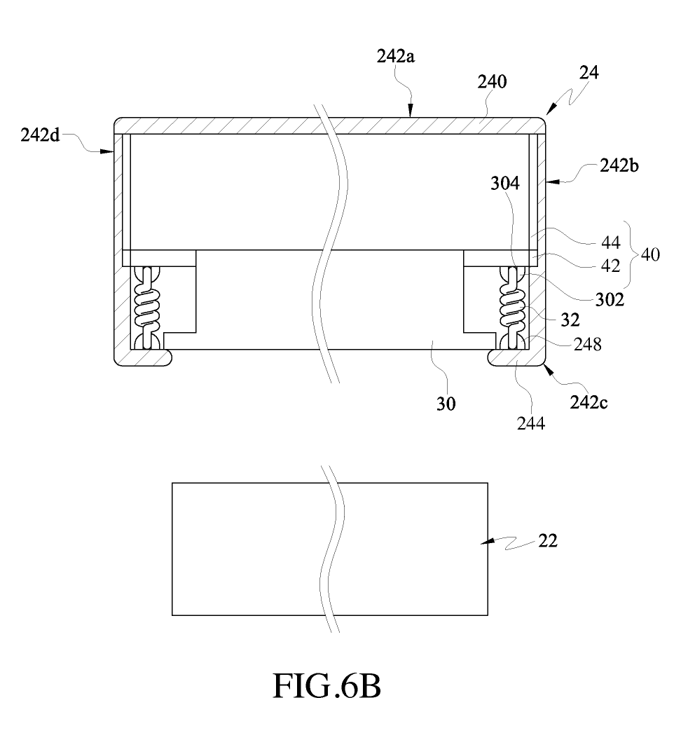

Referring to FIG. 5, in a clamshell electronic device 20a according to another embodiment of the present invention, the restoring component 32a is a tension spring. One end of the restoring component 32a is connected to the combing hole 304 of the moving member 30, and the other end is connected to a connection hole 248 on the side walls 242a, 242b, 242c, and 242d of the second body 24. When the second body 24 is located at the closed position, the moving member 30 is pushed by the first body 22, such that the moving member 30 moves to the received position close to the body portion 240, and the restoring component 32a is tensioned (as shown in FIG. 6A). When the second body 24 is located at the opened position, the moving member 30 is pulled by an elastic restoring force of the restoring component 32 to move to the use position adjacent to the outer edges of the side walls 242a, 242b, 242c, and 242d (as shown in FIG. 6B). Likewise, in order to facilitate the movement of the moving member 30 between the use position and the received position, a guiding component 40 is disposed between the moving member 30 and the second body 24.

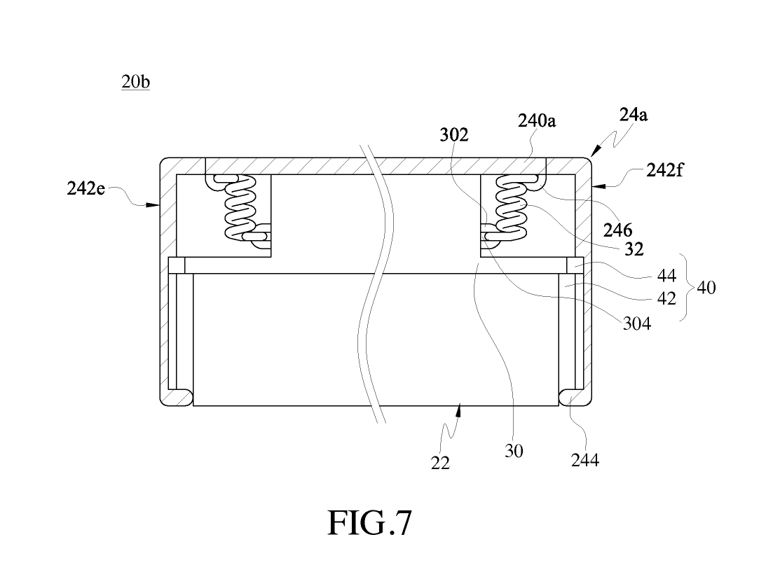

Referring to FIG. 7, a clamshell electronic device 20b in this embodiment has approximately the same structure as those of the above embodiments, so the same members are represented by the same reference numbers and will not be described herein again. A second body 24a has a body portion 240a and side walls 242e and 242f. In this embodiment, a size of the body portion 240a of the second body 24a is substantially equal to the size of the first body 22. In order to enable the side walls 242e and 242f to shield the signal connection ports 226a, 226b, and 226c on the first body 22 when the second body 24a is located at the closed position, the side walls 242e and 242f are bent and extend from side edges of the second body 24a. In this manner, the positions of the side walls 242e and 242f extend outwards, such that no matter whether the size of the body portion 240a is smaller than or equal to the size of the first body 22, the side walls 242e and 242f are sufficient to completely shield the signal connection ports 226a, 226b, and 226c (as shown in FIG. 1) on the first body 22.

Based on the above, the clamshell electronic device of the present invention provides a good protecting effect for the signal connection ports by the design of the side walls. When the second body is located at the closed position, the side walls completely cover the exposed signal connection ports of the first body, thereby protecting the signal connection ports from being damaged due external impacts or contamination with dust or moisture. When the second body is located at the opened position, the signal connection ports are not shielded by the side walls and thus can be directly used, such that the user can conveniently, rapidly and instinctively perform an electrical connection operation.

In addition, since the protecting mechanism for the signal connection port of the present invention does not affect the integrity in appearance of the clamshell electronic device, an integral design can be maintained for the appearance of the clamshell electronic device.

What is claimed is:

1. A clamshell electronic device, comprising:
a first body, having at least one signal connection port on a side edge thereof; and
a second body, rotatably pivoted to the first body, such that the second body has a closed position close to the first body and an opened position forming an angle with the first body, wherein the second body has at least one side wall extending corresponding to the side edge of the first body, and when the second body is located at the closed position, the side wall shields the signal connection port.

2. The clamshell electronic device according to claim 1, further comprising a moving member and a restoring component, wherein one end of the restoring component is connected to the moving member and the other end is connected to the second body, the moving member moves between a received position and a use position through the restoring component, when the second body is located at the closed position, the moving member is moved to the received position, and when the second body is located at the opened position, the moving member is moved to the use position.

3. The clamshell electronic device according to claim 2, wherein the restoring component is a tension spring.

4. The clamshell electronic device according to claim 2, wherein the restoring component is a compression spring.

5. The clamshell electronic device according to claim 2, wherein a guiding component is further disposed between the moving member and the second body, so as to guide the moving member to move between the received position and the use position.

6. The clamshell electronic device according to claim 5, wherein the guiding component comprises a plurality of sliding rails and a plurality of sliding members, the sliding rails are disposed on a side plate, the sliding members are disposed on side edges of the moving member corresponding to the sliding rails, and the sliding members are slideably disposed on the sliding rails.

7. The clamshell electronic device according to claim 1, wherein a handle is further disposed on the side wall.

8. The clamshell electronic device according to claim 1, wherein a waterproof pad is further disposed on an outer edge of the side wall further.

9. A clamshell electronic device, comprising:
a first body, having at least one signal connection port on a side edge thereof; and
a second body, rotatably pivoted to the first body, such that the second body has a closed position close to the first body and an opened position forming an angle with the first body, wherein the second body has a body portion and at least one side wall extending from the body portion corresponding to the side edge of the first body, and when the second body is located at the closed position, the side wall shields the signal connection port.

10. The clamshell electronic device according to claim 9, wherein a size of the body portion is larger than a size of the first body, and the side wall extends from an outer edge of one side of the body portion facing the first body when the second body is located at the closed position.

11. The clamshell electronic device according to claim 9, wherein a size of the body portion is equal to a size of the first body, and the side wall is bent and extends from a side edge of the body portion.

12. The clamshell electronic device according to claim 9, wherein a size of the body portion is smaller than a size of the first body, and the side wall is bent and extends from a side edge of the body portion.

13. The clamshell electronic device according to claim 9, further comprising a moving member and a restoring component, wherein one end of the restoring component is connected to the moving member, the other end is connected to the second body, the moving member moves between a received position and a use position through the restoring component, when the second body is located at the closed position, the moving member is moved to the received position, and when the second body is located at the opened position, the moving member is moved to the use position.

14. The clamshell electronic device according to claim 13, wherein the restoring component is a tension spring.

15. The clamshell electronic device according to claim 13, wherein the restoring component is a compression spring.

16. The clamshell electronic device according to claim 13, wherein a guiding component is further disposed between the moving member and the second body, so as to guide the moving member to move between the received position and the use position.

17. The clamshell electronic device according to claim 16, wherein the guiding component comprises a plurality of sliding rails and a plurality of sliding members, the sliding rails are disposed on a side plate, the sliding members are disposed on side edges of the moving member corresponding to the sliding rails, and the sliding members are slideably disposed on the sliding rails.

18. The clamshell electronic device according to claim 9, wherein a handle is further disposed on the side wall.

19. The clamshell electronic device according to claim 9, wherein a waterproof pad is further disposed on an outer edge of the side wall.
